(19) United States
(12) Patent Application Publication
(10) Pub. No.: US 2006/0207747 A1
(43) Pub. Date: Sep. 21, 2006

(54) Isothermal plate heat-dissipating device

(75) Inventor: Kuo-Len Lin, Wugu Township (TW)

Correspondence Address: HDSL, 4331 STEVENS BATTLE LANE, FAIRFAX, VA, 22033, US

(73) Assignee: CPUMATE INC.

(21) Appl. No.: 11/082,845

(22) Filed: Mar. 18, 2005

(51) Int. Cl. H05K 7/20

(52) U.S. Cl. 165/80.3; 361/700

(57) ABSTRACT

An isothermal plate heat-dissipating device is arranged on a heat-generating element of computer and includes an isothermal plate body and at least one fin plate set. The isothermal plate body comprises an upper panel and a lower panel to define a hollow chamber therein. The hollow chamber contains heat-conducting structure therein. The fin plate set includes a plurality of fin plates and has at least one side in contact with the isothermal plate body. There is large contact area between the isothermal plate body and the fin plate set, thus enhancing the heat dissipation efficiency of the isothermal plate heat-dissipating device.

### BACKGROUND OF THE INVENTION

1. Field of the Invention

The present invention relates to an isothermal plate heat-dissipating device, and more particularly to an isothermal plate heat-dissipating device for heat-generating element of computer and being able to fast dissipate heat.

2. Description of Prior Art

The heat-dissipating device using heat pipe and wick structure has the advantages of high thermal conduction, fast thermal conduction, light weight, simple structure and versatile usage. Therefore, this kind of heat-dissipating device is extensively applied to heat-dissipation of electronic apparatus. More particularly, the heat-dissipating device using heat pipe and wick structure can convey considerable heat without power consumption. The current development trend is to integrate fin set to the heat pipe to form heat pipe heat-dissipating device.

FIG. 1 shows a prior art heat pipe heat-dissipating device, which comprises a base 10a, a plurality of heat pipes 20a and a plurality of fin plates 30a. The base 10a is of plate shape and has a top face in contact with one side of the heat pipe 20a. Another side of the heat pipe 20a is connected to the plurality of fin plates 30a. During application of the heat-dissipating device, the bottom face of the base 10a is arranged atop a heat generating element 40a. The heat generated by the heat generating element 40a is conveyed to the heat pipes 20a and the fin plates 30a through the base 10a, thus dissipating the heat from the heat generating element 40a.

However, the heat pipe 20a in above-mentioned heat-dissipating device only has linear contact area or small contact area with the base 10a and the fin plates 30a. Therefore, it requires considerable time to convey heat from the base 10a to the fin plates 30a through the heat pipe 20a. The heat dissipating efficiency of above-mentioned heat-dissipating device is degraded.

### SUMMARY OF THE INVENTION

The present invention provides an isothermal plate heat-dissipating device, wherein a large contact area is present between the isothermal plate body and the fin plate set. Therefore, the dissipation efficiency of the isothermal plate heat-dissipating device can be enhanced.

Accordingly, the isothermal plate heat-dissipating device is arranged on a heat-generating element of computer and includes an isothermal plate body and at least one fin plate set. The isothermal plate body comprises an upper panel and a lower panel to define a hollow chamber therein. The hollow chamber contains heat-conducting structure therein. The fin plate set includes a plurality of fin plates and has at least one side in contact with the isothermal plate body.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a prior art heat pipe heat-dissipating device.

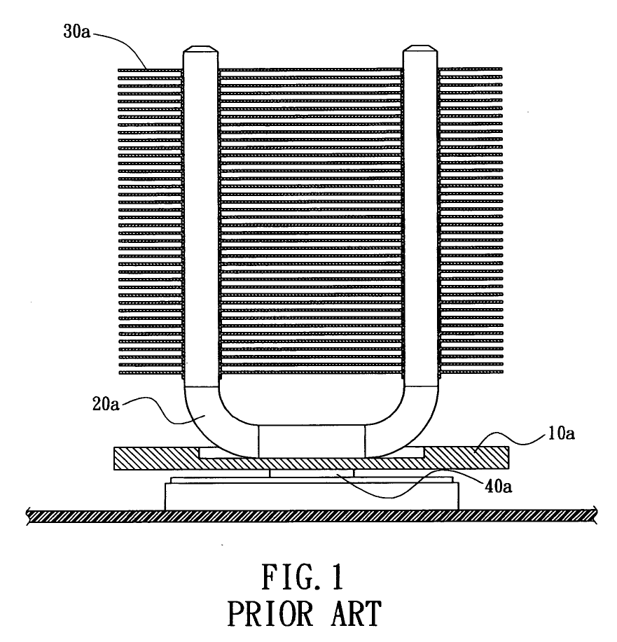

FIG. 2 is an exploded view of the isothermal plate heat-dissipating device according to a first preferred embodiment of the present invention.

FIG. 3 is another exploded view of the isothermal plate heat-dissipating device according to a first preferred embodiment of the present invention.

FIG. 4 shows a sectional view of the first preferred embodiment of the present invention during use.

FIG. 5 shows an exploded view of the isothermal plate body according to a second preferred embodiment of the present invention.

FIG. 6 is an exploded view of the isothermal plate heat-dissipating device according to a second preferred embodiment of the present invention.

FIG. 7 is an exploded view of the isothermal plate heat-dissipating device according to a third preferred embodiment of the present invention.

FIG. 8 is an exploded view of the isothermal plate heat-dissipating device according to a fourth preferred embodiment of the present invention.

FIG. 9 is an exploded view of the isothermal plate heat-dissipating device according to a fifth preferred embodiment of the present invention.

FIG. 10 is an exploded view of the isothermal plate heat-dissipating device according to a sixth preferred embodiment of the present invention.

### DETAILED DESCRIPTION OF THE INVENTION

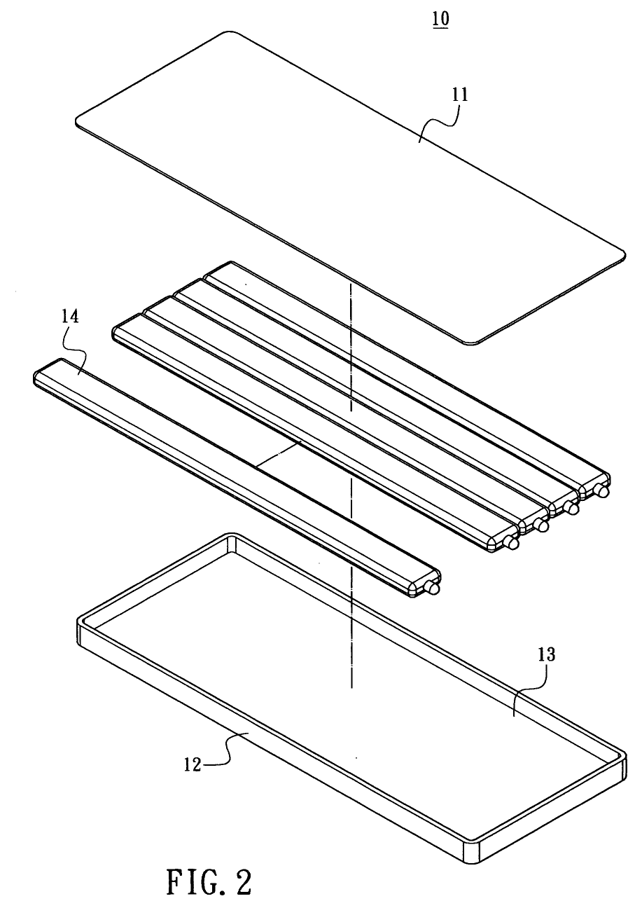

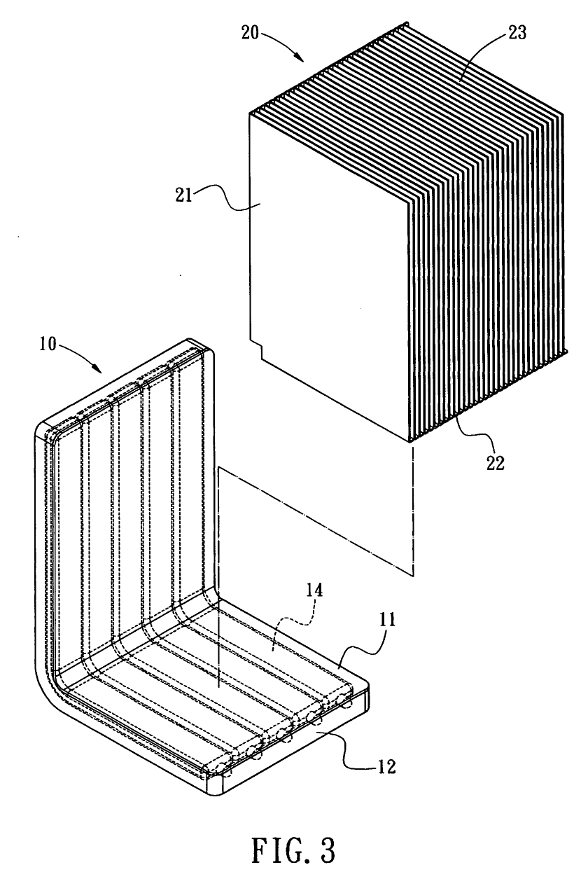

With reference to FIGS. 2 and 3, the isothermal plate heat-dissipating device according to a first preferred embodiment is used for a heat-generating element in a computer and comprises an isothermal plate body 10 and at least fin plate set 20.

The isothermal plate body 10 comprises an upper panel 11 and a lower panel 12 composed of a rectangular bottom face and lateral faces extended upward from peripherals of the bottom face. Therefore, a closed hollow chamber 13 is defined between the upper panel 11 and the lower panel 12 when the upper panel 11 is covered to the lower panel 12. A plurality of heat pipes 14 is arranged in the hollow chamber 13. Each of the heat pipes 14 is of flat shape and contains working fluid and wick structure therein in a vacuum state. The upper face and the lower face of the heat pipe 14 are in contact with the inner face of the upper panel 11 and the inner face of the lower panel 12, respectively. The plurality of heat pipes 14 are in juxtaposed arrangement. After above-mentioned components are assembled, the isothermal plate body 10 is bent to form an L-shaped isothermal plate body 10.

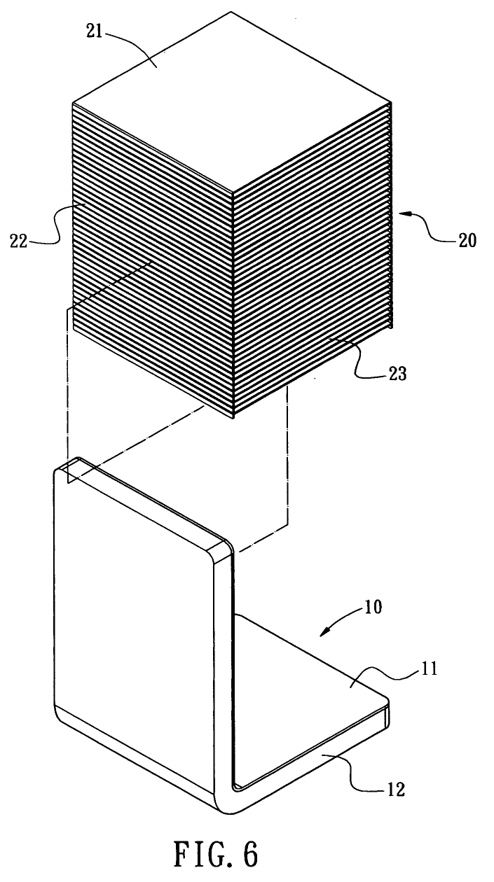

The fin plate set 20 comprises a plurality of fin plates 21 with folded flanges 22 on bottom face and one lateral face thereof, thus increasing the contact surface of the fin plates 21 with the isothermal plate body 10. A runner 23 is defined between two adjacent fin plates 21. The fin plate set 20 can be arranged in longitudinal or transversal manner (see FIG. 6) on the upper panel 11. In the shown embodiment, the fin plate set 20 is arranged in longitudinal manner.

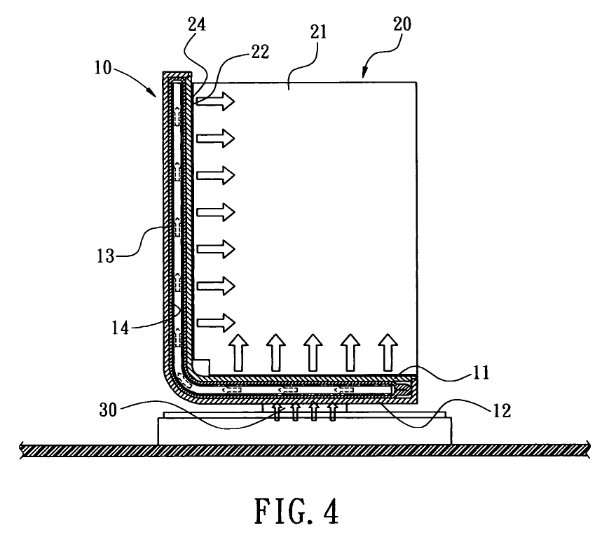

To assemble the isothermal plate heat-dissipating device, a heat conducting material 24 is pasted on surface of the folded flange 22 or on surface of the isothermal plate body 10, as shown in FIG. 4. The heat conducting medium 24 can be, for example, heat-conducting slurry or tin slurry to enhance hermetic property and lubrication between the isothermal plate body 10 and the fin plates 21.

FIG. 4 shows a sectional view of the first preferred embodiment of the present invention during use. The bottom face of the lower panel 12 is in contact with a heat-generating element 30 such as a CPU when the isothermal plate heat-dissipating device is used. The heat generated from the heat-generating element 30 is absorbed by the lower panel 12 and then conveyed to the heat pipes 14. The heat is then conveyed to top of the isothermal plate body 10 by air-liquid phase change in the heat pipes 14. The isothermal plate body 10 is contacted to the fin plate set 20 with large contact area. Therefore heat can be fast conveyed to the fin plates 21, thus enhancing heat dissipating effect.

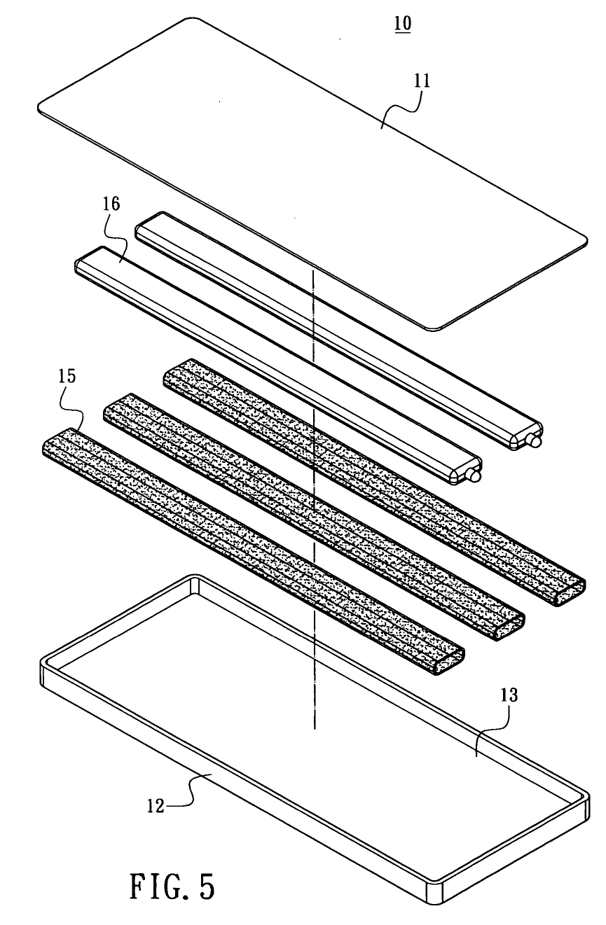

FIG. 5 shows an exploded view of the isothermal plate body 10 according to another preferred embodiment of the present invention. The hollow chamber 13 is provided with wick structures 15 and heat-conducting bodies 16 in juxtaposition arrangement therein besides the heat pipes 14. The upper panel 11, the lower panel 12, the wick structures 15 and the heat-conducting bodies 16 are preformed by bending and then assembled together by soldering a junction between the upper panel 11 and the lower panel 12. Moreover a working fluid (not shown) is injected therein and the isothermal plate body 10 is vacuumed therein. The heat-conducting body 16 can be a heat pipe, a supporter or other thermo-conducting device.

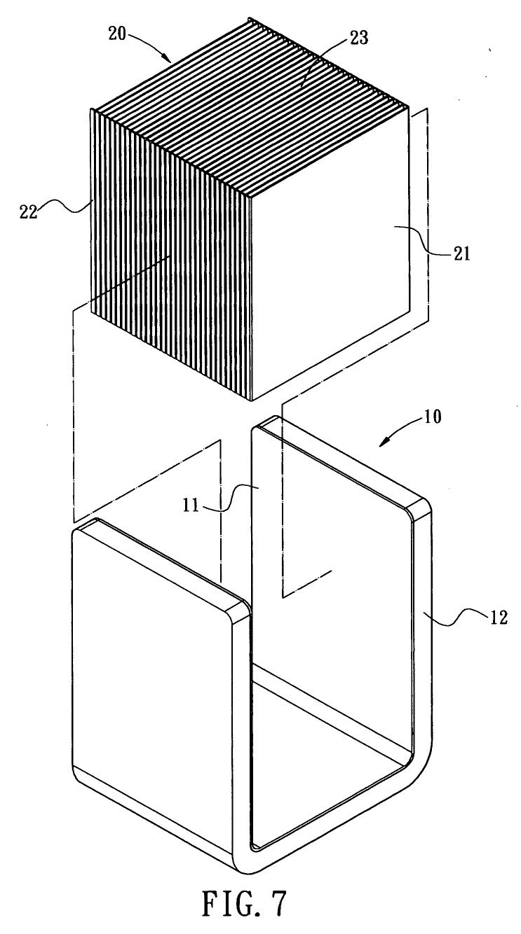

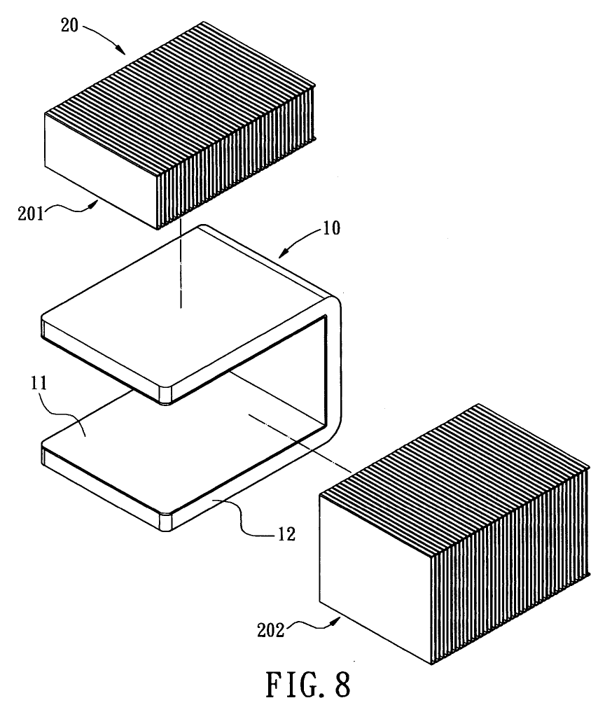

FIGS. 7 and 8 show the exploded views of the third and fourth preferred embodiments of the present invention, respectively. The isothermal plate body 10 can be of U shape or inverted U shape (as shown in FIG. 8). The fin plate set 20 has folded flanges 22 on opposite sides thereof and arranged in longitudinal or transversal manner (not shown) on the upper panel 11. Therefore, the folded flanges 22 are in close contact with the isothermal plate body 10. The fin plate set 20 comprises a first fin plate set 201 and a second fin plate set 202. One face of the first fin plate set 201 is in contact with a top outer face of the lower panel 12. Both faces of the second fin plate set 202 are in contact with the two opposite faces of the upper panel 11. Therefore the contact area between the fin plates 21 and the isothermal plate body 10 can be advantageously increased. The arrangement and configuration of the fin plate set 20 can be adjusted according to the ambient of the computer and the heat amount generated by the heat generating element.

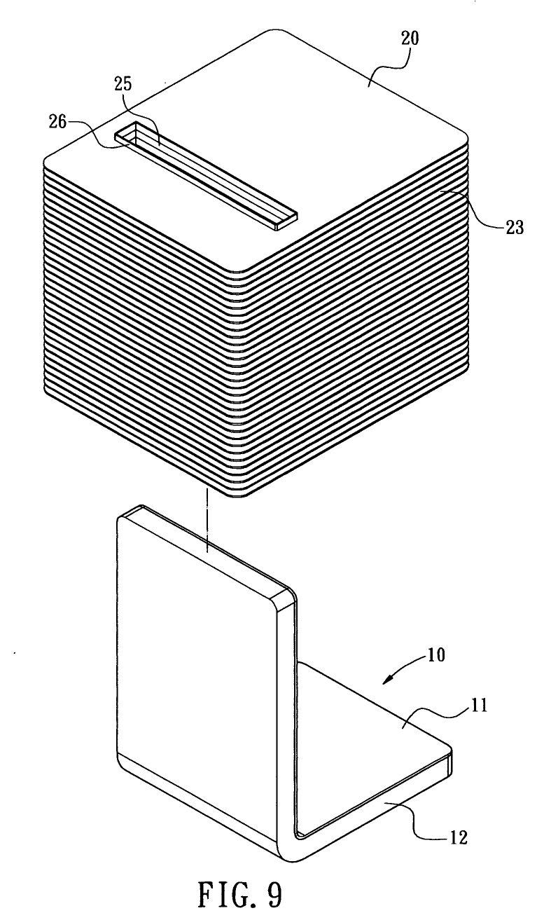

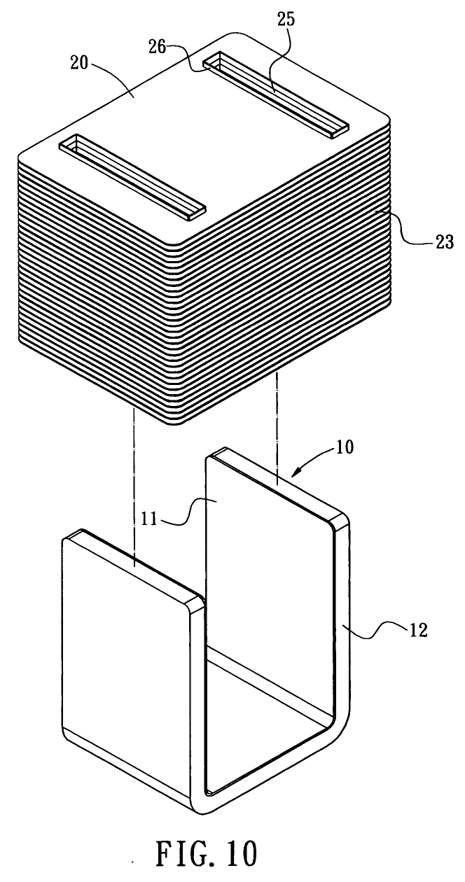

FIGS. 9 and 10 how the exploded views of the fifth and sixth preferred embodiments of the present invention, respectively. The fin plate 21 of the fin plate set 20 can be provided with an elongated hole 25 and a tab 26 is extended upward from a peripheral of the elongated hole 25. A heat conducting medium 24 is pasted on inner surface of the tab 26 (with reference to FIG. 4). The fin plate set 20 is then mounted on the isothermal plate body 10 by passing the isothermal plate body 10 through the elongated hole 25. Moreover, the fin plate set 20 can be provided with two elongated holes 25 and the fin plate set 20 is then mounted on a U-shaped isothermal plate body 10. Therefore, the isothermal plate heat-dissipating device comprises a heat absorbing end in contact with the heat generating element and two heat-dissipating ends in serial connection with the isothermal plate body 10, thus enhancing the heat dissipating efficiency of the isothermal plate heat-dissipating device.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. An isothermal plate heat-dissipating device, comprising
an isothermal plate body comprising a hollow chamber, a plurality of heat pipes in the hollow chamber, the heat pipe comprising working fluid and wick structure therein; and
at least one fin plate set comprising a plurality of fin plates, each of the fin plates comprising an elongated hole through which the isothermal plate body passes.

2. The isothermal plate heat-dissipating device as in claim 1, wherein the isothermal plate body is one of U shape, inverted U shape and L shape.

3. The isothermal plate heat-dissipating device as in claim 1, wherein the isothermal plate body comprises an upper panel and a lower panel to define the hollow chamber therebetween.

4. The isothermal plate heat-dissipating device as in claim 3, wherein each of the heat pipes is of flat shape with an upper face and a lower face in contact with an inner face of the upper panel and an inner face of the lower panel, respectively.

5. The isothermal plate heat-dissipating device as in claim 4, wherein the heat pipes are in juxtaposition arrangement.

6. The isothermal plate heat-dissipating device as in claim 1, wherein a tab is extended from a peripheral of the elongated hole.

7. The isothermal plate heat-dissipating device as in claim 1, further comprising a heat conducting medium provided between the isothermal plate body and the elongated hole.

8. An isothermal plate heat-dissipating device comprising
an isothermal plate body comprising a hollow chamber, a plurality of heat pipes in the hollow chamber, the heat pipe comprising working fluid and wick structure therein; and
at least one fin plate set comprising a plurality of fin plates, the fin plate set having at least one side in contact with the isothermal plate body.

9. The isothermal plate heat-dissipating device as in claim 8, wherein the isothermal plate body is one of U shape, inverted U shape and L shape.

10. The isothermal plate heat-dissipating device as in claim 8, wherein the isothermal plate body comprises an upper panel and a lower panel to define the hollow chamber therebetween.

11. The isothermal plate heat-dissipating device as in claim 10, wherein each of the heat pipes is of flat shape with an upper face and a lower face in contact with an inner face of the upper panel and an inner face of the lower panel, respectively.

12. The isothermal plate heat-dissipating device as in claim 11, wherein the heat pipes are in juxtaposition arrangement.

13. The isothermal plate heat-dissipating device as in claim 10, wherein the fin plate set is arranged in longitudinal or transversal manner on the upper panel.

14. The isothermal plate heat-dissipating device as in claim 10, wherein the fin plate set comprises a first fin plate set and a second fin plate set, one face of the first fin plate set being in contact with a top outer face of the lower panel, both faces of the second fin plate set being in contact with two opposite faces of the upper panel.

15. The isothermal plate heat-dissipating device as in claim 10, wherein the fin plate set comprises a first fin plate set and a second fin plate set, one face of the first fin plate set being in contact with a top outer face of the lower panel, one end of the second fin plate set being in contact with a bottom face of the upper panel.

16. The isothermal plate heat-dissipating device as in claim 8, further comprising a heat conducting medium provided between the isothermal plate body and the fin plate set.

17. The isothermal plate heat-dissipating device as in claim 8, wherein the fin plate comprises folded flange on lateral side thereof.

18. An isothermal plate heat-dissipating device comprising
an isothermal plate body comprising a hollow chamber, the hollow chamber containing wick structure, heat-conducting body, and working fluid and therein and being in a vacuum state; and
at least one fin plate set comprising a plurality of fin plates, the fin plate set having at least one side in contact with the isothermal plate body.

19. The isothermal plate heat-dissipating device as in claim 18, wherein the heat-conducting body can be one of a heat pipe and a supporter.
